(19) United States
(12) Patent Application Publication
(10) Pub. No.: US 2014/0070171 A1
(43) Pub. Date: Mar. 13, 2014

(54) Infrared Organic Light-Emitting Diode

(71) Applicants: Yawei Liu, Shenzhen City (CN); Liuyang Yang, Shenzhen City (CN); Xing Feng, Shenzhen City (CN)

(72) Inventors: Yawei Liu, Shenzhen City (CN); Liuyang Yang, Shenzhen City (CN); Xing Feng, Shenzhen City (CN)

(73) Assignee: Shenzhen China Star Optoelectronics Technology Co. Ltd., Shenzhen City, Guangdong Province (CN)

(21) Appl. No.: 13/703,867

(22) PCT Filed: Sep. 28, 2012
(86) PCT No.: PCT/CN12/82237

§ 371 Date: Dec. 12, 2012

(30) Foreign Application Priority Data
Sep. 11, 2012 (CN) 201210334452.4

(51) Int. Cl. H01L 51/50

(52) U.S. Cl. CPC H01L 51/5004
USPC 257/40

(57) ABSTRACT

The present invention provides an infrared organic light-emitting diode, which includes a light-transmitting substrate, an anode arranged on the light-transmitting substrate, a hole transporting layer arranged on the anode, a light emission layer arranged on the hole transporting layer, a hole blocking layer arranged on the light emission layer, an electron transporting layer arranged on the hole blocking layer, and a cathode arranged on the electron transporting layer. The light emission layer is an infrared light emission layer. The infrared organic light-emitting diode uses the infrared light emission layer to emit infrared light so as to overcome the drawbacks of high manufacturing cost, complicated operation, and being not able to form a film on polycrystalline, amorphous, or flexible plastic substrate found in the inorganic semiconductor infrared devices and thus lower down the manufacture cost to quite an extent and provides versatile utilization to help popularization

### BACKGROUND OF THE INVENTION

1. Field of the Invention

The present invention relates to the field of an organic light-emitting diode, and in particular to an infrared organic light-emitting diode.

2. The Related Arts

Infrared band, which has a wavelength of 0.78-1,000 μm, is an important electromagnetic waveband in military and civil applications. Infrared light is commonly used in heating, physiotherapy, night vision, communication, navigation, vegetable cultivation, and animal and poultry farming. Taking infrared physiotherapy as an example, when infrared light is irradiated on body surface, a portion of the infrared light is reflected, while the other portion is absorbed by skin. The extent of reflection of the infrared light is related to skin pigmentation. When irradiation is made with infrared light of wavelength of 0.9 micrometer, skin with no pigmentation will reflect about 60% of the light energy, while skin with pigmentation will reflect about 40% of the light energy. When irradiation is made with long wavelength infrared light (having a wavelength greater than 1.5 micrometers), most of the light is reflected and absorbed by surface layer of skin, penetrating only a depth of 0.05-2 mm into the skin. Consequently, it only works for the surface layer tissue of the skin. Short wavelength infrared light (having a wavelength less than 1.5 micrometers) and near infrared component of the infrared light can penetrate into the tissue to the greatest depth, which can be as large as 10 millimeters, so as to directly work on the vessels, lymphatic vessels, and nerve terminals of skin and other subcutaneous tissues to provide a desired therapeutic effect.

Commonly applications of infrared light in regular living include high temperature sterilization, infrared night vision devices, surveillance devices, infrared port of mobile phones, hotel key cards, remote controls of automobiles and television sets, infrared sensor for washing basins, and infrared sensor doors. Further, window wavelengths of fiber optic communication, including 850 nm, 1330 nm, and 1550 nm, are within the infrared band. Further, infrared band is also involved in various applications, including data processing, storage, security marking, infrared survey, and infrared guidance.

Commonly known infrared generation devices include gaseous xenon lamps, heated objects, and laser devices, but they are not capable of infrared displaying. Inorganic semiconductor infrared generation devices are based on inorganic compounds containing primarily tellurium, cadmium, and mercury. The inorganic infrared semiconductor materials have certain drawbacks, including high manufacturing cost, complicated operation, and being not able to form a film on polycrystalline, amorphous, or flexible plastic substrate. These drawbacks of the inorganic infrared semiconductor material impose limitation to wide application of infrared components in military use.

Contrary to the inorganic semiconductor materials, organic semiconductor materials show advantages of being cheap and light-weighted, good solubility, being easy to form large-area flexible components, and being capable of regulating opto-electrical performance through molecular tailoring. An organic light-emitting diode has advantages of wide range material selectability, low driving voltage, high response speed, large view angle, light weight, being ultra thin, flexible substrates, large area, and mass production.

Infrared organic light-emitting diode (OLED) displays are made of organic semiconductor materials and the displayed image is invisible to bear eyes and can only be viewed with night vision goggles. Thus, integration of the display with uniforms or equipments of solders allows the solders to do communication in the nighttime without being found by enemies and also provides the capability of viewing through fog and rain. Further, the infrared organic light-emitting diode display can also be used to open house door or car door and transmission of enciphered message.

Thus, researches of infrared organic light-emitting diode are of scientific significance and wide applications in the future.

### SUMMARY OF THE INVENTION

An object of the present invention is to provide an infrared organic light-emitting diode, which has a simple structure and low cost and may realize flexible infrared displaying.

To achieve the object, the present invention provides an infrared organic light-emitting diode, which comprises a light-transmitting substrate, an anode arranged on the light-transmitting substrate, a hole transporting layer arranged on the anode, a light emission layer arranged on the hole transporting layer, a hole blocking layer arranged on the light emission layer, an electron transporting layer arranged on the hole blocking layer, and a cathode arranged on the electron transporting layer. The light emission layer is an infrared light emission layer.

The infrared light emission layer is a trivalent rear earth ion complex layer, a narrow band gap organic polymer layer, an organic ion dye layer, a porphyrin layer, or a phthalocyanine layer.

The infrared light emission layer comprises a plurality of uniformly distributed pixel points thereon, each of the pixel units comprising an infrared sub-pixel point, each of the pixel units being driven by a TFT circuit.

The light-transmitting substrate comprises a glass substrate.

The anode comprises an indium tin oxides layer formed on the light-transmitting substrate; the hole transporting layer comprises a layer of N,N′-di(3-methylphenyl)-N,N′-biphenyl-1,1′-biphenyl-4,4′-diamine or N,N′-di(1-naphthyl)-N,N′-biphenyl-1,1′-biphenyl-4,4′-diamine; the hole blocking layer comprises a layer of 1,3,5-(benzenetriyl)tris(1-phenyl-1H-benzimidazole) or 2,9-dimethyl-4,7-diphenyl-1,10-phenanthroline; the electron transporting layer comprises a layer of doped 8-hydroxyquinoline aluminum; and the cathode comprises a layer of aluminum or silver.

The light-transmitting substrate comprises a flexible polyethylene terephthalate substrate or a flexible stainless steel foil.

The infrared organic light-emitting diode further comprises a first protection layer arranged between the anode and the light-transmitting substrate and a second protection layer arranged on the cathode.

The first protection layer comprises a layer of alternating structure of polymer layers and inorganic densified cut-off layers.

The polymer layers comprise parylene layers, polyalkene layers, polyester layers, or polyimide layers.

The second protection layer comprises a titanium dioxide layer, a silicon dioxide layer, an aluminum oxide layer, a silicon nitride layer, a silicon oxynitride layer, a silicon oxycarbide layer, or a diamond-like carbon layer.

The present invention also provides an infrared organic light-emitting diode, which comprises a light-transmitting substrate, an anode arranged on the light-transmitting substrate, a hole transporting layer arranged on the anode, a light emission layer arranged on the hole transporting layer, a hole blocking layer arranged on the light emission layer, an electron transporting layer arranged on the hole blocking layer, and a cathode arranged on the electron transporting layer, the light emission layer being an infrared light emission layer;

wherein the infrared light emission layer is a trivalent rear earth ion complex layer, a narrow band gap organic polymer layer, an organic ion dye layer, a porphyrin layer, or a phthalocyanine layer;

wherein the infrared light emission layer comprises a plurality of uniformly distributed pixel points thereon, each of the pixel units comprising an infrared sub-pixel point, each of the pixel units being driven by a TFT circuit;

wherein the anode comprises an indium tin oxides layer formed on the light-transmitting substrate; the hole transporting layer comprises a layer of N,N′-di(3-methylphenyl)-N,N′-biphenyl-1,1′-biphenyl-4,4′-diamine or N,N′-di(1-naphthyl)-N,N′-biphenyl-1,1′-biphenyl-4,4′-diamine; the hole blocking layer comprises a layer of 1,3,5-(benzenetriyl)tris(1-phenyl-1H-benzimidazole) or 2,9-dimethyl-4,7-diphenyl-1,10-phenanthroline; the electron transporting layer comprises a layer of doped 8-hydroxyquinoline aluminum; and the cathode comprises a layer of aluminum or silver;

wherein the light-transmitting substrate comprises a flexible polyethylene terephthalate substrate or a flexible stainless steel foil;

further comprising a first protection layer arranged between the anode and the light-transmitting substrate and a second protection layer arranged on the cathode;

wherein the first protection layer comprises a layer of alternating structure of polymer layers and inorganic densified cut-off layers;

wherein the polymer layers comprise parylene layers, polyalkene layers, polyester layers, or polyimide layers; and

wherein the second protection layer comprises a titanium dioxide layer, a silicon dioxide layer, an aluminum oxide layer, a silicon nitride layer, a silicon oxynitride layer, a silicon oxycarbide layer, or a diamond-like carbon layer.

The efficacy of the present invention is that the present invention provides an infrared organic light-emitting diode, which comprises an infrared light emission layer to allow the infrared organic light-emitting diode to emit infrared light for overcoming the drawbacks of high manufacturing cost, complicated operation, and being not able to form a film on polycrystalline, amorphous, or flexible plastic substrate found in the inorganic semiconductor infrared devices and thus lower down the manufacture cost to quite an extent and provides versatile utilization to help popularization.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 is a schematic view showing the structure of an infrared organic light-emitting diode according to an embodiment of the present invention;

FIG. 2 is a schematic view showing the structure of pixel of infrared organic light-emitting diode according to the present invention;

FIG. 3 is a schematic view showing a circuit diagram of pixel driving circuit of infrared organic light-emitting diode according to the present invention;

FIG. 4 is a plot showing peak of emission spectrum for a light emission layer made of copper phthalocyanine;

FIG. 5 is a plot showing peak of emission spectrum for a light emission layer made of tris(8-hydroxyquinolinato)erbium;

FIG. 6 is a schematic view showing the structure of an infrared organic light-emitting diode according to another embodiment of the present invention; and

FIG. 7 is a schematic view illustrating a first protection layer of FIG. 6.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

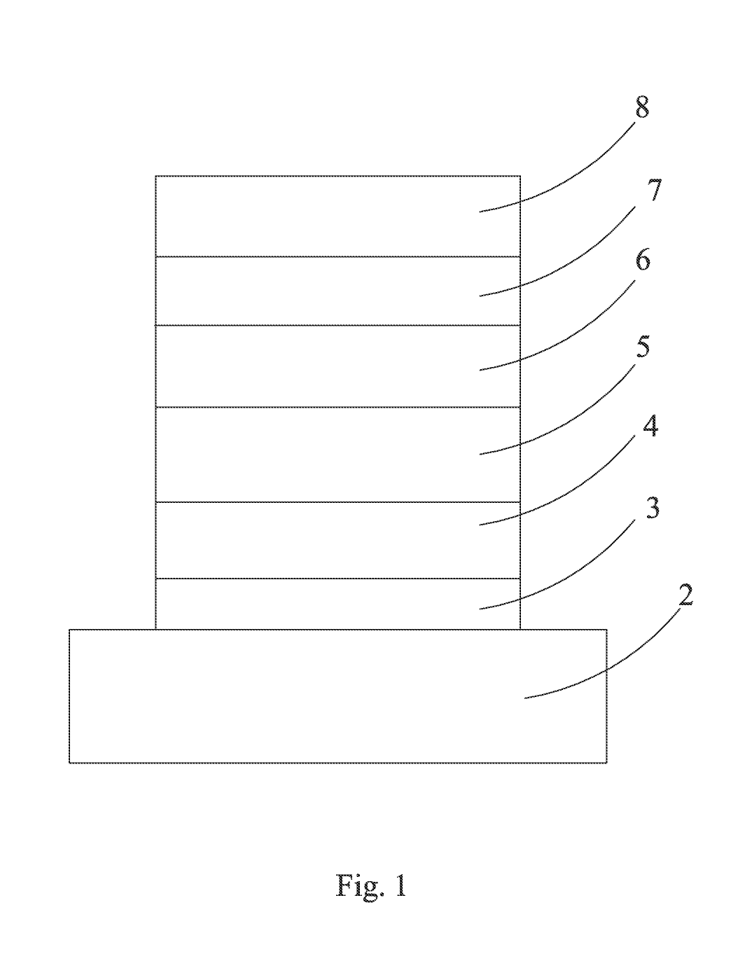

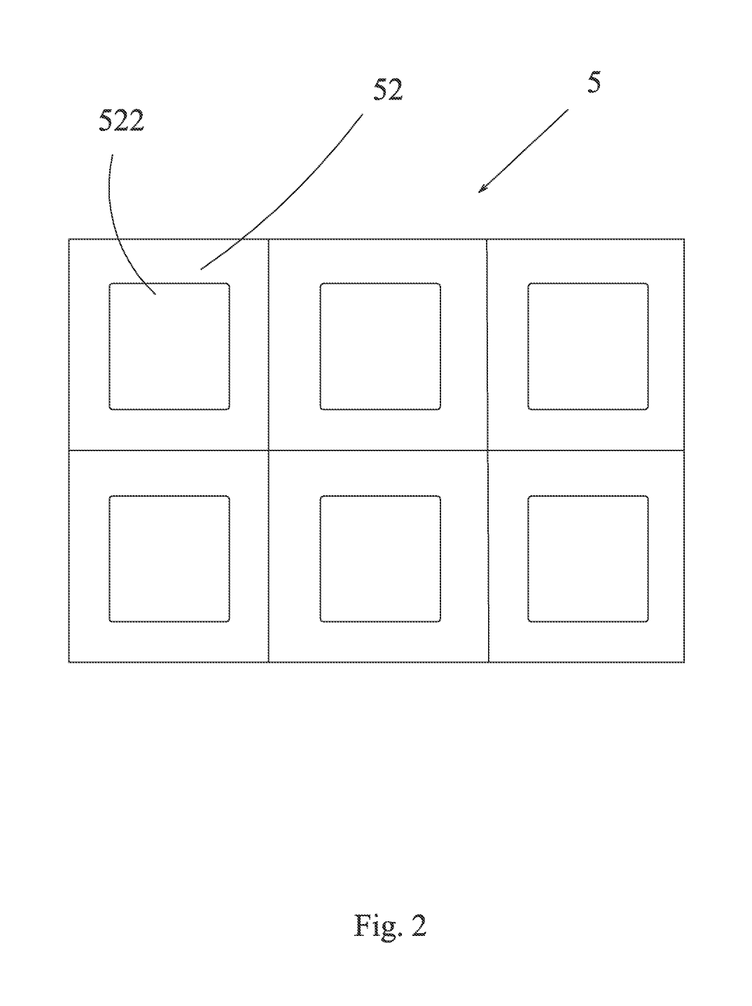

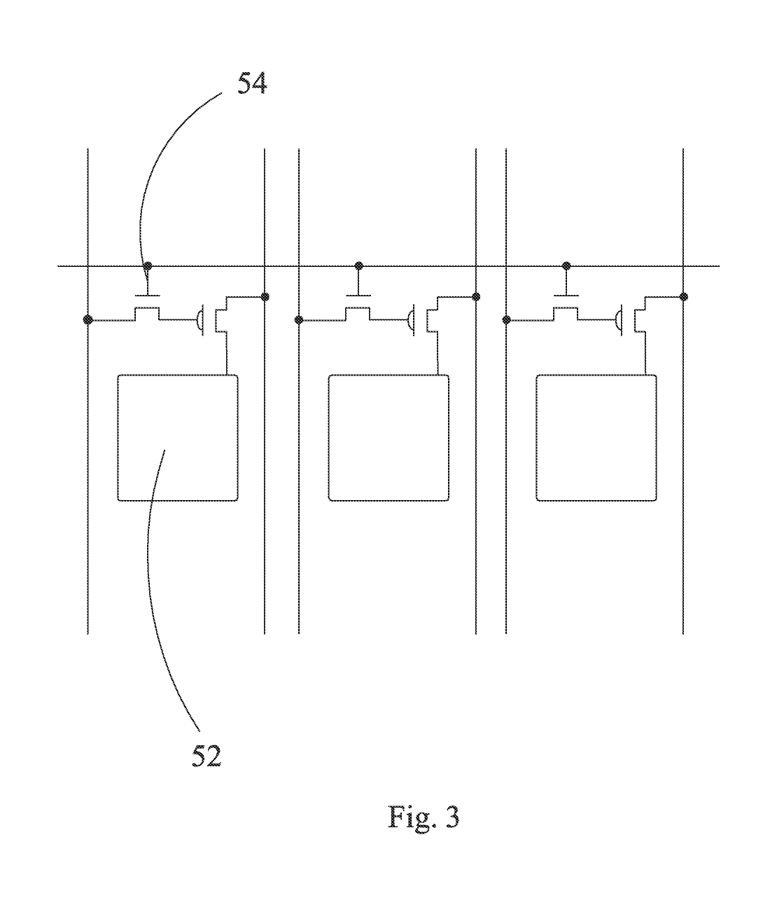

Referring to FIGS. 1-5, the present invention provides an infrared organic light-emitting diode, which comprises: a light-transmitting substrate 2, an anode 3 arranged on the light-transmitting substrate 2, a hole transporting layer 4 arranged on the anode 3, a light emission layer 5 arranged on the hole transporting layer 4, a hole blocking layer 6 arranged on the light emission layer 5, an electron transporting layer 7 arranged on the hole blocking layer 6, and a cathode 8 arranged on the electron transporting layer 7.

In the instant embodiment, the light-transmitting substrate 2 comprises a glass substrate. The anode 3 comprises indium tin oxides (ITO) formed on the light-transmitting substrate. The hole transport layer 4 comprises a layer of N,N′-di(3-methylphenyl)-N,N′-biphenyl-1,1′-biphenyl-4,4′-diamine (TPD) or a layer of N,N′-di(1-naphthyl)-N,N′-biphenyl-1,1′-biphenyl-4,4′-diamine (NPD). The light emission layer 5 comprises an infrared light emission layer. The hole blocking layer 6 comprises a layer of 1,3,5-(benzenetriyl)tris(1-phenyl-1H-benzimidazole) (TPBI) or a layer of 2,9-dimethyl-4,7-diphenyl-1,10-phenanthroline (BCP). The electron transporting layer 7 comprises a layer of doped 8-hydroxyquinoline aluminum (Alq₃). The cathode comprises aluminum (Al) or silver (Ag).

The infrared light emission layer 5 can be a trivalent rear earth ion complex layer, a narrow band gap organic polymer layer, an organic ion dye layer, a porphyrin layer, or a phthalocyanine layer. The infrared light emission layer 5 comprises a plurality of uniformly distributed pixel points 52 thereon. Preferably, the pixel points 52 are arranged to juxtapose each other. Each pixel point 52 comprises an infrared sub-pixel point 522. Each pixel point 52 is driven by a TFT circuit 54.

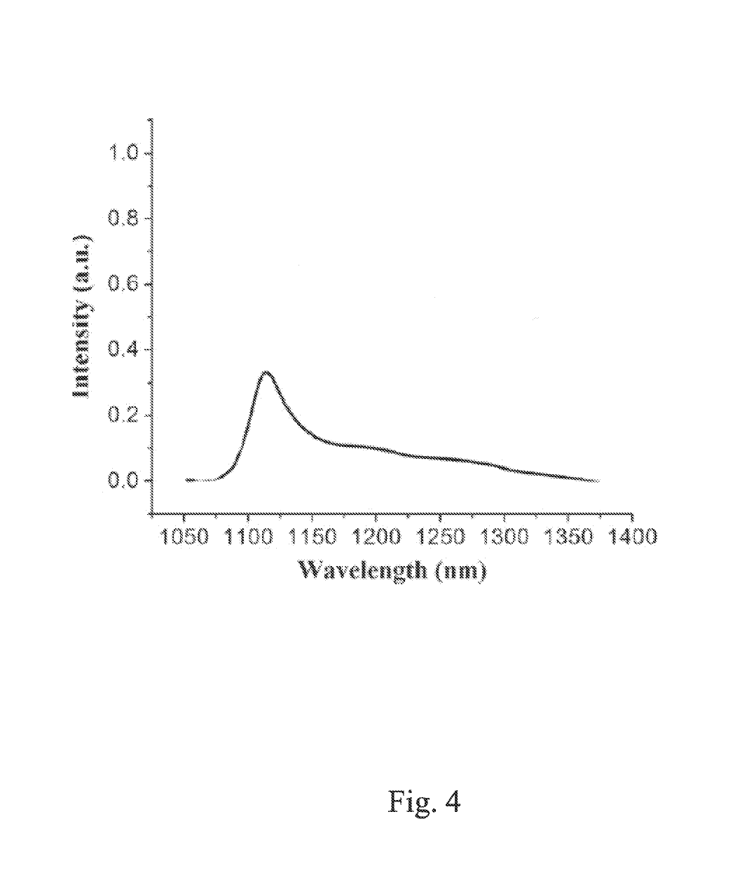

Referring to FIG. 4, which is a plot showing peak of emission spectrum for a light emission layer made of copper phthalocyanine, it is noted that the peak of the emission spectrum is at 1,120 nm, which belongs to the infrared waveband. Copper phthalocyanine material has the following formula:

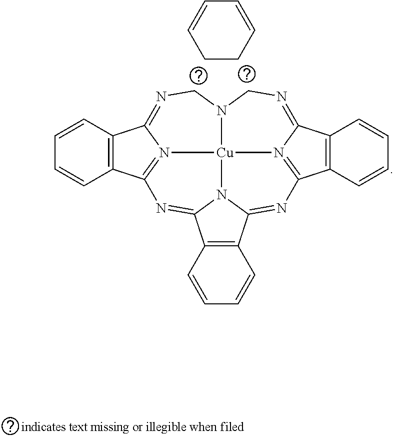

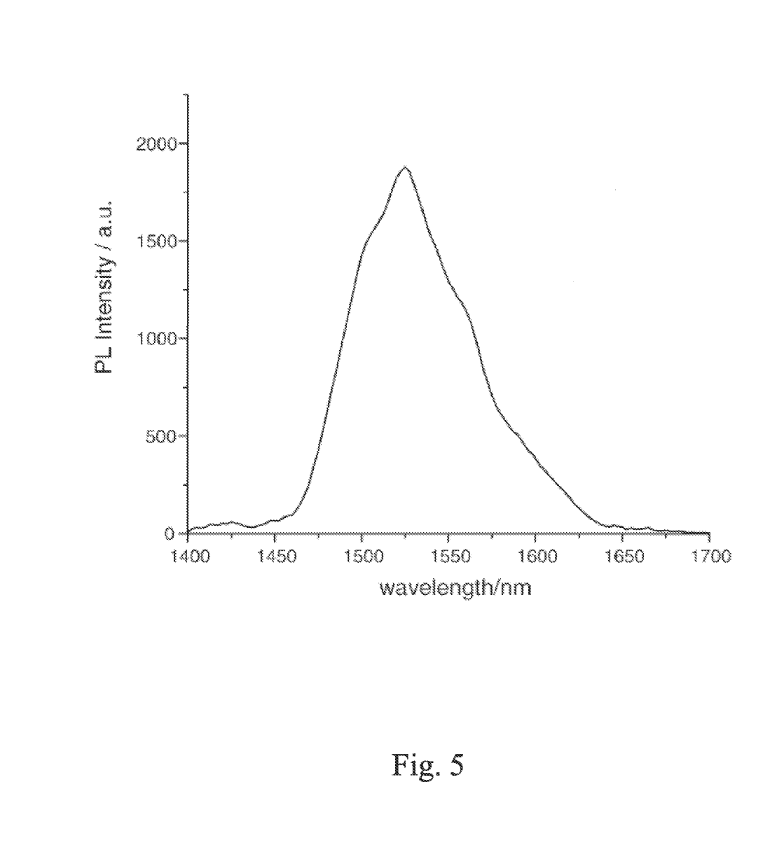

Referring to FIG. 5, which is a plot showing peak of emission spectrum for a light emission layer made of tris(8-hydroxyquinolinato)erbium, it is noted that the peak of the emission spectrum is at 1,530 nm, which belongs to the infrared waveband. Tris(8-hydroxyquinolinato)erbium material has the following formula:

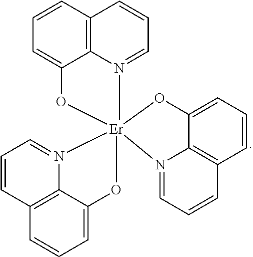

It can be noted that the infrared organic light-emitting diode according to the present invention generate light having a wavelength in the range of infrared wavelength and can be used as an infrared generation device to thereby overcome the drawbacks of inorganic semiconductor infrared components that are of high cost, complicated manufacturing operation, being incapable of forming a film on polycrystalline, amorphous, or flexible plastic substrate, and can also be used for infrared displaying, allowing message transmission in the nighttime or by related personnel without exposing the message.

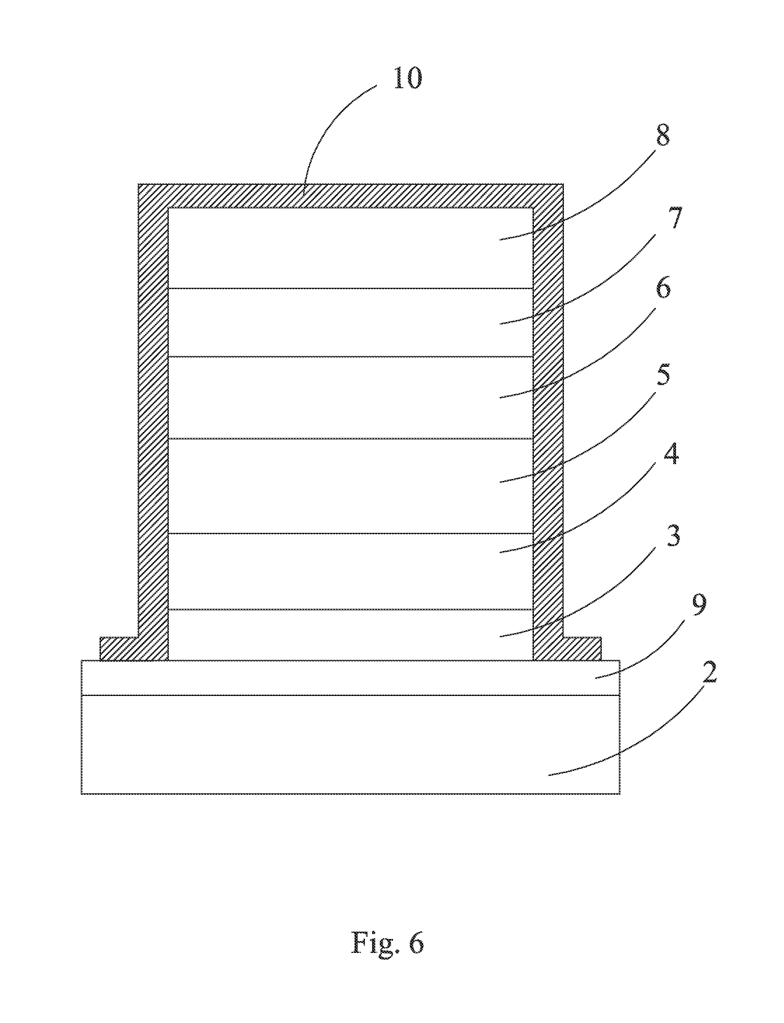

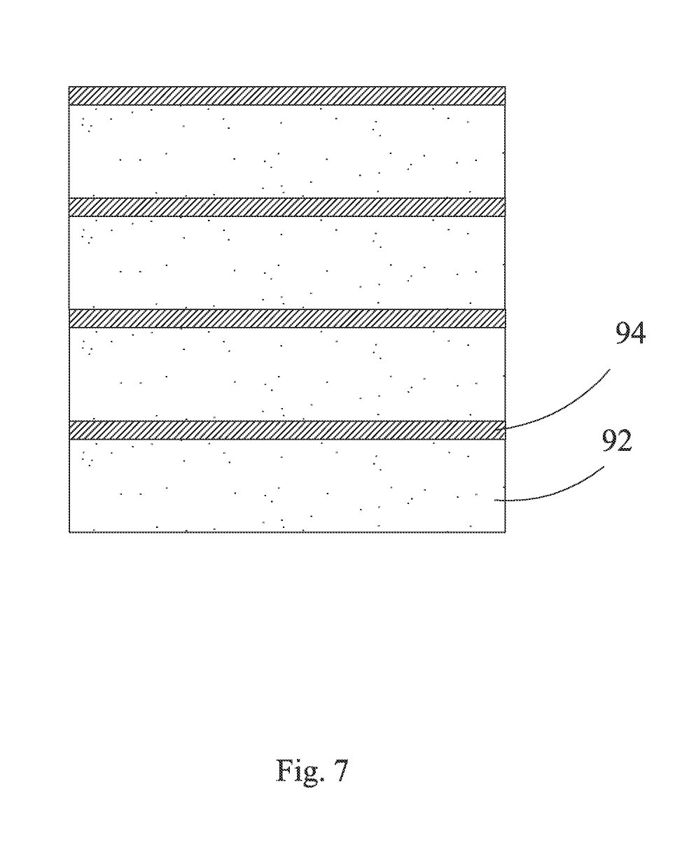

Referring to FIGS. 6 and 7, schematic views showing an infrared organic light-emitting diode according to another embodiment of the present invention are given, in the instant embodiment, the infrared organic light-emitting diode comprises a light-transmitting substrate 2 that is a flexible polyethylene terephthalate substrate or a flexible stainless steel foil and further comprises a first protection layer 9 arranged between the anode 3 and the light-transmitting substrate 2 and a second protection layer 10 arranged on the cathode 8.

In the instant embodiment, the first protection layer 9 is a Barix protection layer, which is a layer of alternating structure of polymer layers 92 and inorganic densified cut-off layers 94.

The polymer layers 92 can be parylene layers, polyalkene layers, polyester layers, or polyimide layers. The parylene layer is preferably poly (p-xylylene) (PPX) or poly (chloro-p-xylene) (PCPX). The polyalkene layer is preferably polyethylene (PE), polystyrene (PS), polypropylene (PP), polyethylene terephthalate (PET), or polytetrafluoroethylene (PTFE), perfluoroalkoxy (PFA). The polyester layer is preferably polyethylene naphthalate (PEN), polycarbonate (PC), polymethylmethacrylate (PMMA), polyvinyl acetate (PVAC), or polyethersulfone (PES).

The densified cut-off layers 94 can be transparent oxide film, transparent fluoride film, silicon nitride series (SiₓN_{y}), or chalcogenide glass. The transparent oxide film can be titanium dioxide (TiO₂), magnesium oxide (MgO), silicon dioxide (SiO₂), zirconium oxide (ZrO₂), zinc oxide (ZnO), or aluminum oxide (Al₂O₃). The transparent fluoride film can be lithium fluoride (LiF) or magnesium fluoride (MgF₂). The silicon nitride series can be silicon nitride (Si₃N₄), titanium nitride (TiN), or silicon nitride (SiNₓ). The chalcogenide glass can be selenium (Se), tellurium (Te), or antimony (Sb). The others are zinc sulfide (ZnS), silicon oxynitride (SiOₓN_{y}), silicon oxycarbide (SiOₓC_{y}).

The second protection layer 10 is an inorganic protection layer, which can be a titanium dioxide (TiO₂) layer, a silicon dioxide (SiO₂) layer, an aluminum oxide (Al₂O₃) layer, a silicon nitride (SiNₓ) layer, a silicon oxynitride (SiOₓN_{y}) layer, a silicon oxycarbide (SiOₓC_{y}) layer, or a diamond-like carbon (DLC) layer.

The infrared organic light-emitting diode of the present invention can be used as an infrared generation device and can also serve as an infrared displaying device.

To serve as an infrared light generation device, the following uses are provided:

(1) It can be used in heating, physiotherapy, night vision, communication, navigation, vegetable cultivation, and animal and poultry farming. When infrared light is irradiated on body surface, a portion of the infrared light is reflected, while the other portion is absorbed by skin. Skin pigmentation is related to reflection of the infrared light. When irradiation is made with infrared light of wavelength of 0.9 micrometer, skin with no pigmentation will reflect about 60% of the light energy, while skin with pigmentation will reflect about 40% of the light energy. When irradiation is made with long wavelength infrared light (having a wavelength greater than 1.5 micrometers), most of the light is reflected and absorbed by surface layer of skin, penetrating only a depth of 0.05-2 mm into the skin. Consequently, it only works for the surface layer tissue of the skin. Short wavelength infrared light (having a wavelength less than 1.5 micrometers) and near infrared component of the infrared light can penetrate into the tissue to the greatest depth, which can be as large as 10 millimeters, so as to directly work on the vessels, lymphatic vessels, and nerve terminals of skin and other subcutaneous tissues to provide a desired therapeutic effect.

(2) Common activities in regular living including high temperature sterilization, infrared night vision devices, surveillance devices, infrared port of mobile phones, hotel key cards, remote controls of automobiles and television sets, infrared sensor for washing basins, and sensor doors of hotels, are all realized with application of infrared light.

To serve as infrared displaying devices, the uses are as follows:

A flexible infrared organic light-emitting diode display is invisible to bear eyes and can only be viewed with night vision goggles. Thus, integration of the display with uniforms or equipments of solders allows the solders to do communication in the nighttime without being found by enemies and also provides the capability of viewing through fog and rain.

Further, the infrared organic light-emitting diode can also be used as an infrared inspection device.

In summary, the present invention provides an infrared organic light-emitting diode, which comprises an infrared light emission layer to allow the infrared organic light-emitting diode to emit infrared light for overcoming the drawbacks of high manufacturing cost, complicated operation, and being not able to form a film on polycrystalline, amorphous, or flexible plastic substrate found in the inorganic semiconductor infrared devices and thus lower down the manufacture cost to quite an extent and provides versatile utilization to help popularization.

Based on the description given above, those having ordinary skills of the art may easily contemplate various changes and modifications of the technical solution and technical ideas of the present invention and all these changes and modifications are considered within the protection scope of right for the present invention.

What is claimed is:

1. An infrared organic light-emitting diode, comprising: a light-transmitting substrate, an anode arranged on the light-transmitting substrate, a hole transporting layer arranged on the anode, a light emission layer arranged on the hole transporting layer, a hole blocking layer arranged on the light emission layer, an electron transporting layer arranged on the hole blocking layer, and a cathode arranged on the electron transporting layer, the light emission layer being an infrared light emission layer.

2. The infrared organic light-emitting diode as claimed in claim 1, wherein the infrared light emission layer is a trivalent rear earth ion complex layer, a narrow band gap organic polymer layer, an organic ion dye layer, a porphyrin layer, or a phthalocyanine layer.

3. The infrared organic light-emitting diode as claimed in claim 2, wherein the infrared light emission layer comprises a plurality of uniformly distributed pixel points thereon, each of the pixel units comprising an infrared sub-pixel point, each of the pixel units being driven by a TFT circuit.

4. The infrared organic light-emitting diode as claimed in claim 1, wherein the light-transmitting substrate comprises a glass substrate.

5. The infrared organic light-emitting diode as claimed in claim 1, wherein the anode comprises an indium tin oxides layer formed on the light-transmitting substrate; the hole transporting layer comprises a layer of N,N′-di(3-methylphenyl)-N,N′-biphenyl-1,1′-biphenyl-4,4′-diamine or N,N′-di(1-naphthyl)-N,N′-biphenyl-1,1′-biphenyl-4,4′-diamine; the hole blocking layer comprises a layer of 1,3,5-(benzenetriyl)tris(1-phenyl-1H-benzimidazole) or 2,9-dimethyl-4,7-diphenyl-1,10-phenanthroline; the electron transporting layer comprises a layer of doped 8-hydroxyquinoline aluminum; and the cathode comprises a layer of aluminum or silver.

6. The infrared organic light-emitting diode as claimed in claim 1, wherein the light-transmitting substrate comprises a flexible polyethylene terephthalate substrate or a flexible stainless steel foil.

7. The infrared organic light-emitting diode as claimed in claim 6 further comprising a first protection layer arranged between the anode and the light-transmitting substrate and a second protection layer arranged on the cathode.

8. The infrared organic light-emitting diode as claimed in claim 7, wherein the first protection layer comprises a layer of alternating structure of polymer layers and inorganic densified cut-off layers.

9. The infrared organic light-emitting diode as claimed in claim 8, wherein the polymer layers comprise parylene layers, polyalkene layers, polyester layers, or polyimide layers.

10. The infrared organic light-emitting diode as claimed in claim 7, wherein the second protection layer comprises a titanium dioxide layer, a silicon dioxide layer, an aluminum oxide layer, a silicon nitride layer, a silicon oxynitride layer, a silicon oxycarbide layer, or a diamond-like carbon layer.

11. An infrared organic light-emitting diode, comprising: a light-transmitting substrate, an anode arranged on the light-transmitting substrate, a hole transporting layer arranged on the anode, a light emission layer arranged on the hole transporting layer, a hole blocking layer arranged on the light emission layer, an electron transporting layer arranged on the hole blocking layer, and a cathode arranged on the electron transporting layer, the light emission layer being an infrared light emission layer;
wherein the infrared light emission layer is a trivalent rear earth ion complex layer, a narrow band gap organic polymer layer, an organic ion dye layer, a porphyrin layer, or a phthalocyanine layer;
wherein the infrared light emission layer comprises a plurality of uniformly distributed pixel points thereon, each of the pixel units comprising an infrared sub-pixel point, each of the pixel units being driven by a TFT circuit;
wherein the anode comprises an indium tin oxides layer formed on the light-transmitting substrate; the hole transporting layer comprises a layer of N,N′-di(3-methylphenyl)-N,N′-biphenyl-1,1′-biphenyl-4,4′-diamine or N,N′-di(1-naphthyl)-N,N′-biphenyl-1,1′-biphenyl-4,4′-diamine; the hole blocking layer comprises a layer of 1,3,5-(benzenetriyl)tris(1-phenyl-1H-benzimidazole) or 2,9-dimethyl-4,7-diphenyl-1,10-phenanthroline; the electron transporting layer comprises a layer of doped 8-hydroxyquinoline aluminum; and the cathode comprises a layer of aluminum or silver;
wherein the light-transmitting substrate comprises a flexible polyethylene terephthalate substrate or a flexible stainless steel foil;
further comprising a first protection layer arranged between the anode and the light-transmitting substrate and a second protection layer arranged on the cathode;
wherein the first protection layer comprises a layer of alternating structure of polymer layers and inorganic densified cut-off layers;
wherein the polymer layers comprise parylene layers, polyalkene layers, polyester layers, or polyimide layers; and
wherein the second protection layer comprises a titanium dioxide layer, a silicon dioxide layer, an aluminum oxide layer, a silicon nitride layer, a silicon oxynitride layer, a silicon oxycarbide layer, or a diamond-like carbon layer.
